(19) United States
(12) Patent Application Publication
(10) Pub. No.: US 2004/0132235 A1
(43) Pub. Date: Jul. 8, 2004

(54) Silicon thin film transistor, a method of manufacture, and a display screen

(76) Inventors: Brahim Dahmani, Bourron Marlotte (FR); Guillaume Guzman, Veneux-les-Sablons (FR); Sonia Mechken, Paris (FR)

Correspondence Address: CORNING INCORPORATED, SP-TI-3-1, CORNING, NY, 14831

(21) Appl. No.: 10/668,877

(22) Filed: Sep. 23, 2003

(30) Foreign Application Priority Data
Sep. 24, 2002 (FR) 0211793

(51) Int. Cl. H01L 21/00; C30B 1/00; H01L 21/324; H01L 21/84; H01L 21/42

(52) U.S. Cl. 438/166; 438/486; 438/795

(57) ABSTRACT

In a first aspect, the present invention provides a silicon thin film transistor which comprises:

a substrate;

a barrier layer of porous silica (SiO₂) deposited directly on the substrate; and

a thin layer of silicon that has been caused to be polycrystalline deposited directly on the barrier layer.

The invention also provides a method of manufacturing such a transistor, a display screen including such a transistor, and a method of manufacturing such a display screen.

### RELATED APPLICATION

This application claims the benefit of priority from French Patent Application No. 02-11793, filed, Sep. 24, 2002, the content of which is incorporated herein by reference.

### FIELD OF INVENTION

The present invention relates to a silicon thin film transistor, its method of manufacture, and a display screen including it.

### BACKGROUND

Silicon thin film transistors are used in numerous fields, including the field of flat display screens, such as active matrix liquid crystal display screens and active matrix display screens having an organic light-emitting layer. In such screens, each pixel or light point is controlled by a silicon thin film transistor, hence the term “active matrix”. At present, flat active matrix liquid crystal display screens are for the most part manufactured using hydrogenated amorphous silicon, also written a-Si:H for the device that activates and deactivates a pixel. Hydrogenated amorphous silicon, however, exhibit limited carrier mobility, and for this reason it cannot be used for manufacturing the activation, deactivation, and addressing circuits of the screen in reliable manner.

Workers in the field, therefore, have proposed using thin film transistors based on polycrystalline silicon, which have a carrier mobility that exceeds by two orders of magnitude the carrier mobility of thin-film transistor active devices based on amorphous silicon. Hence, thin film transistors based on polycrystalline silicon enable one not only to integrate peripheral control circuits with the screen, but also one to attain better resolution.

At present, thin film transistors based on polycrystalline silicon are manufactured by depositing a layer of amorphous silicon on a substrate, followed by crystallizing the silicon constituting said thin layer by irradiating it with an excimer laser. The method, however, presents several drawbacks. First, the energy of the laser light is limited in quantity and is very expensive. For example, at present, industrial lasers are limited to energy of less than 1 joule at 300 Hz. This drawback is particularly significant for substrates of large area. In order to maintain the same laser fluence (i.e. laser energy per unit area) needed for crystallizing a large area, the laser must be capable of delivering much greater amounts of energy. Second, the size of the silicon grains needs to be increased in order to achieve better integration. Unfortunately, in order to increase silicon grain size, the speed at which the silicon solidifies must be slowed down, and to do that heat energy must be prevented from flowing from the film of molten silicon into the cooled substrate.

To solve those problems, several strategies have been proposed but, unfortunately, have not proven satisfactory. A proposal to heat the substrate is limited by the fact that the substrate is generally made of glass, and such heating is limited up to only about 400° C. Alternatively, some have suggested using a laser to deliver dual pulses and dual beams, with both sides of the substrate being radiated by the light beams coming from an excimer laser. Another idea was to use a barrier layer of crystalline silica having density close to its theoretical density, the barrier layer being interposed between the substrate and the thin film of silicon. The thermal barrier effect of such a dense crystalline silica layer is not sufficient. Hence an unsatisfied need still exists, which the present invention can fulfill.

### SUMMARY OF THE INVENTION

To overcome the deficiencies of these strategies, the present invention provides polycrystalline silicon thin film transistors comprising:

a substrate;

a barrier layer of porous silica deposited directly on the substrate; and

a thin film of silicon that has been caused to be polycrystalline, deposited directly on the barrier layer. The silicon thin film transistor has grains of increased and uniform size, while eliminating the flow of heat energy from the molten silicon constituting said thin layer into the substrate of the silicon thin film transistor. For this purpose, the invention describes placing a barrier layer between the substrate and the thin film of silicon, the barrier layer being made of a material that is porous and that has thermal conductivity lower than the thermal conductivity of the substrate. The silicon thin film has a thickness in the range from about 50 nm to about 80 nm. The size of the polycrystalline silicon grains of the thin film is about 1 micrometer (μm), and the substrate is made of glass. The barrier layer has a thickness in the range from about 150 nanometers (nm) to about 1,000 nm, and preferably in the range from about 400 nm to about 600 nm. The barrier layer has a porosity ratio lying in the range from 20% to 90%, and preferably lying in the range from about 30% to about 60%.

The invention also provides a method of manufacturing a silicon thin film transistor as described. The method comprises the following steps:

a) depositing a porous silica barrier layer directly on a substrate;

b) depositing a porous silicon thin film directly on the barrier layer; and

c) irradiating the thin film of silicon using a laser to obtain a thin film of polycrystalline silicon.

Optionally, the method further comprises, between step b) and step c), a step of dehydrogenating the silicon of the thin film of amorphous silicon.

Preferably a sol-gel process is used to deposit the barrier layer of amorphous silicon, and a plasma-assisted chemical vapor deposition is used to deposit the thin film of amorphous silicon in step b). In step c), an excimer laser, operating at 248 nm or at 308 nm, preferably at 308 nm, to irradiate the thin film of silicon. The thickness of the thin silicon film is in the range of from about 20 nm to about 80 nm.

The invention also pertains to a display screen that includes at least one silicon thin film transistor according to the present invention, or made according to the present method. The invention also provides a method of manufacturing a display screen, characterized in that it includes the method of manufacturing a silicon thin film transistor of the invention.

Additional features and advantages of the present invention will be revealed in the following detailed description. Both the foregoing summary and the following detailed description and examples are merely representative of the invention, and are intended to provide an overview for understanding the invention as claimed.

### BRIEF DESCRIPTION OF THE FIGURES

The invention will be better understood and other objects and advantages thereof will appear more clearly on reading the following description which is made with reference to the accompanying figures.

FIG. 1 shows the structure of a silicon thin film transistor while it is being irradiated.

FIG. 2 shows a polycrystalline silicon thin film transistor obtained after irradiation.

### DETAILED DESCRIPTION OF THE INVENTION

In the manufacture of a silicon thin film transistor according to the present invention, the first step of the method includes depositing on a substrate (1), as depicted in the figures, a barrier layer (2) of material that is porous and that has thermal conductivity lower than the thermal conductivity of the substrate (1). Preferably the substrate is a glass substrate; and even more preferably a substrate made of aluminosilicate, borosilicate, or alumino-borosilicate, like Corning 1737 glass.

A particularly suitable material for forming the barrier layer 2 is silica (SiO₂) having porosity ratio lying in the range from about 20% to about 90%. If the porosity ratio is less than 20%, then the thermal barrier effect of the layer 2 is poor and the layer 2 needs to be thicker. If the porosity ratio is greater than 90%, then the layer 2 becomes fragile and difficult to handle, even though the thermal barrier effect is excellent for porosity ratio greater than 90%. The barrier layer 2 preferably has a porosity ratio in the range of from about 30% to about 60%. In such a range barrier layer 2 presents the best compromise between the thermal barrier effect, fragility, and thickness.

The porosity ratio of the barrier layer 2 is calculated using the following formula:

$$porosity ratio = 1 - \frac{{n}^{2} - 1}{{n}_{d}^{2} - 1}$$

where n is the refractive index of the porous material and n_{d} is the refractive index of the dense material. The refractive indices of materials are measured by molecular probe ellipsometry as described on pages 7 to 13 of the article by F. Horowitz entitled “Towards better control of sol-gel film processing for optical device applications” published in the Journal of Non-linear Optical Physics and Materials, Vol. 6, No. 1 (1997).

The barrier layer 2 of porous silica is advantageously deposited according to a sol-gel method, and is preferably constituted by amorphous silica. Preferably, the barrier layer 2 has a thickness in the range of from about 400 nm to about 600 nm. When the thickness of the barrier layer 2 lies in the range from about 150 nm to about 1,000 nm, we found surprisingly that the barrier layer can act as a buffer against heat transmission even. This attribute of the barrier layer is particularly advantageous, specifically when manufacturing flat screens.

Equally surprising, the barrier layer 2 can act not only as a thermal barrier, but also as a chemical barrier, in spite of the fact that it is porous. The barrier layer 2 can prevent elements constituting the substrate or any other layer present on or under said barrier layer migrating to the other layers under the effect of an electric field or of heat.

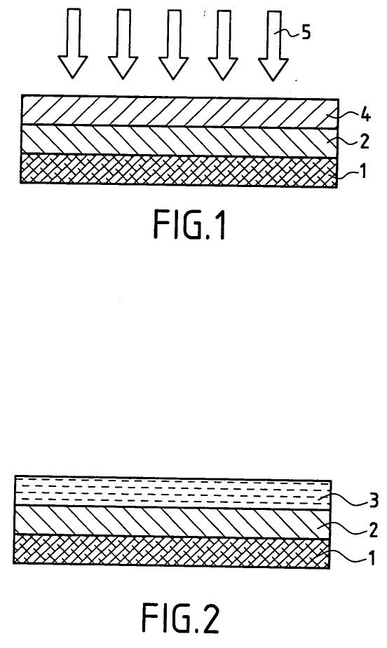

In a second step of the method of manufacturing the thin film transistor of the invention includes depositing a layer of amorphous silicon, referenced 4 in FIG. 1, directly onto the barrier layer 2. Advantageously, the thin film of amorphous silicon 4 is of thickness lying in the range from about 20 nm to about 80 nm. Preferably, its thickness lies in the range from 50 nm to 80 nm.

An optional third step of the method of the invention for manufacturing a polycrystalline silicon thin film transistor involves dehydrogenating the resulting stacked structure, in particular in dehydrogenating the amorphous silicon. This step is advantageously performed by heating the structure to 450° C. under nitrogen for 1 hour.

The fourth step of the method of the invention for manufacturing a polycrystalline silicon thin film transistor is represented in FIG. 1, and relates to using laser light, referenced 5 in FIG. 1, so as to crystallize the silicon, to irradiate the thin film of amorphous silicon, referenced 4 in FIG. 1.

Although the transistor of the invention is constituted by a stack of layers including the substrate 1, the barrier layer 2 deposited on the substrate, and the thin film 3 of polycrystalline silicon deposited directly on the barrier layer 2, the polycrystalline silicon layer 3 is not deposited directly on the barrier layer 2 in the form of a layer of silicon that is already polycrystalline, but in the form of a layer of amorphous silicon which is subsequently caused to be polycrystalline.

This crystallization is advantageously implemented by using an excimer laser which presents the advantage of enabling the silicon of the amorphous layer to melt on the surface only, thus making it possible to reduce the thickness of the barrier layer 2.

There are several types of excimer layer operating at five different wavelengths depending on the gas used: F₂ (157 nm); ArF (193 nm); KrF (248 nm); XeCl (308 nm); and XeF (351 nm). The KrF wavelength (248 nm) and the XeCl wavelength (308 nm) are preferably used in the context of the invention since these are the wavelengths that correspond most closely to the absorption coefficient of silicon.

Two approaches to crystallizing silicon with a 308 nm laser coexist: a single shot approach and an approach of scanning the surface, also referred to as a multi-shot approach.

The single shot approach is made possible by using a very high power laser capable of processing a 5 centimeter square (5 cm×5 cm) in a single shot. Such a laser is sold in particular by the Company SOPRA. As a general rule, the pulse duration of such a laser is 200 nanoseconds (ns). With that type of laser, the fluence required to crystallize the silicon is very high.

The multi-shot or surface scanning approach is possible using XeCl lasers with pulse durations lying in the range approximately from 20 ns to 30 ns. Such lasers are less powerful than the laser sold by SOPRA. Surface scanning is performed using a special optical unit which enables a light strip having a length of 30 cm to 40 cm and a width of less than 1 millimeter (mm) to scan the plate that is to be processed.

Thus, in the invention, it is preferable to use an excimer laser operating at 248 nm or at 308 nm in order to crystallize the thin film of amorphous silicon. Nevertheless, and more preferably, an excimer layer operating at 308 nm is used.

Preferably, one employs a multi-shot irradiation method.

Because of the presence of the barrier layer 2, it is possible to perform such multi-shot irradiation. In addition, the barrier layer 2 enables all of the heat in the amorphous silicon layer 4 to be conserved, thus reducing the fluence (necessary light energy per unit area) that is required from the laser, consequently enabling the cost of manufacturing such a polycrystalline silicon thin film transistor to be reduced.

Nevertheless, lasers operating in the visible can also be used for irradiating the thin film of silicon, even though under such circumstances it is necessary to increase the thickness of the barrier layer 2.

Excimer lasers suffer from various faults, such as high maintenance costs, problems of beam stability, and lifetime of the optical system.

Lasers operating in the visible range, and mainly at a green wavelength, such as Nd:YAG lasers can also be used. However, under such circumstances, the absorption of silicon in the green generally makes it preferable to use thicker films of silicon, e.g. films having a thickness of 250 nm, whereas with a laser excimer operating at 248 nm or at 308 nm, the thickness of the silicon film generally lies in the range from 20 nm to 80 nm.

The thin film of amorphous silicon 4 can be deposited by any method, but it is preferably deposited by plasma-assisted chemical vapor deposition.

After irradiation, the structure shown in FIG. 2 is obtained, i.e. a substrate referenced 1 in FIG. 2, preferably made of Corning 1737 glass, having a barrier layer referenced 2 deposited directly thereon, preferably made of silica that is amorphous and porous, said barrier layer 2 itself being directly coated with a thin film of polycrystalline silicon that is referenced 3 in FIG. 2.

The size of the silicon grains in the layer 3 is greater than or equal to 1 μm, and in the invention this is obtained, surprisingly, by using fluence that is at least 30% less than the fluence needed for obtaining the same size of silicon grains with the prior art method in which a barrier layer is used that is made of non-porous silica.

The following steps of the manufacturing method of the invention are steps performed in conventional manner in methods of manufacturing polycrystalline silicon thin film transistors, and consist in depositing the layers necessary for obtaining the desired transistors.

In order to make the invention better understood, there follows a description of examples that are purely illustrative and non-limiting.

### EXAMPLE 1

As shown in FIG. 1, the substrate 1 was a Corning 1737 glass substrate. It was 1 mm thick. A barrier layer 2 of amorphous silicon having porosity ratio of 50% was deposited on the substrate 1 using a sol-gel method. The thickness of the barrier layer 2 was 150 nm. The resulting layer 2 was entirely suitable for being handled, and it enabled an excellent thermal and chemical barrier to be obtained using a thickness of only 150 nm. Thereafter, plasma-assisted chemical vapor deposition was used to deposit a layer 4 of amorphous silicon on the free surface of the barrier layer 2. This layer 4 of amorphous silicon was 55 nm thick.

Thereafter, the layer 4 of amorphous silicon was dehydrogenated under nitrogen at a temperature of 450° C. for 1 hour.

Multi-shot irradiation was then performed on said layer 4 of amorphous silicon using a KrF excimer layer operating at 248 nm with pulses having a duration of 20 ns, thereby crystallizing the silicon of the layer 4. The light energy needed from the laser per unit area, i.e. the fluence, was 160 millijoules per square centimeter (mJ/cm²).

This resulted in a thin film 3 of polycrystalline silicon having grains of 1 μm size. The grains were uniform in size. Thereafter subsequent layers were deposited.

### COMPARATIVE EXAMPLE 1

A prior art thin film transistor was made. For this purpose, a crystalline silica layer having porosity ratio lower than 2% was deposited on a 1 mm thick Corning 1737 glass substrate. The thickness of the layer was 150 nm. Thereafter, as in Example 1, an amorphous silicon layer was deposited on the free surface of the dense crystalline silica layer. The amorphous silicon was dehydrogenated under nitrogen at a temperature of 450° C. for 1 hour. Thereafter, the amorphous silicon was crystallized by multi-shot irradiation using a KrF excimer layer operating at 248 nm with pulses of 20 ns duration. The fluence needed from the laser in order to obtain silicon grains having a uniform size of 1 μm was 220 mJ/cm². The subsequent layers were then deposited.

### EXAMPLE 2

The procedure was the same as in Example 1, however an XeCl laser was used operating at 308 nm in order to crystallize the silicon of the amorphous silicon layer 4. As in Example 1, a layer 3 of polycrystalline silicon was obtained with grains of uniform size of appropriately 1 μm. Nevertheless, in order to obtain grains of this size, the fluence required of the XeCl laser used was 210 mJ/cm².

### COMPARATIVE EXAMPLE 2

The procedure was the same as in Example 2 except that the barrier layer 2 was a non-porous silica layer, i.e. having a porosity ratio lower than 2% and a thickness of 150 nm. The fluence needed from the XeCl laser used in order to obtain a layer 3 of polycrystalline silicon having uniform grain size of appropriately 1 μm was 300 mJ/cm².

It can be seen from the above examples and comparative examples that by using a barrier layer of the invention, the laser fluence needed for obtaining grains of polycrystalline silicon of given size is smaller than that needed when using a barrier layer of non-porous silicon.

In general, in the other examples that have been performed using other types of laser, and in particular excimer layers, the presence of the barrier layer of the invention causes the fluence needed from the laser to crystalline the silicon of the thin layer of amorphous silicon to be reduced by at least 30%.

It can also be seen from Example 1 and Example 2 that using a KrF laser is more advantageous in terms of fluence.

In spite of that, it is preferable from an industrial point of view to use an XeCl laser in the invention since XeCl lasers are in more widespread use because of their better reliability and lifetime.

Naturally, the invention is not limited in any way to the embodiments described and shown. Any material other than porous and amorphous silica could be used to form the barrier layer, the only conditions required of this layer are that it should be made of a material that is compatible both with the substrate material and with the silicon constituting the thin film of the transistor of the invention, and that said material should have thermal conductivity that is less than that of the substrate.

In the same way, when the barrier layer is made of amorphous and porous silica, any method of deposition that appears suitable to the person skilled in the art other than deposition by a sol-gel method could also be used without thereby going beyond the ambit of the invention. That is, the invention covers all technical equivalents of the means described and any combinations thereof providing they come within the spirit of the invention. The substrate for the thin film transistor, however, need not be glass. For example, the substrate could be a plastic or a metal material, the only condition being that it can withstand the temperatures used in the process of manufacturing the transistor.

The present invention has been described both in general and in detail by way of examples. Persons skilled in the art will understand that the invention is not limited necessarily to the specific embodiments disclosed. Modifications and variations may be made without departing from the scope of the invention as defined by the following claims or their equivalents, including equivalent components presently known, or to be developed, which may be used within the scope of the present invention. Hence, unless changes otherwise depart from the scope of the invention, the changes should be construed as being included herein.

We claim:

1. A silicon thin film transistor comprising:
a substrate;
a barrier layer of porous silica (SiO₂) deposited directly on said substrate; and
a thin film of silicon that has been caused to be polycrystalline, deposited directly on said barrier layer.

2. The silicon thin film transistor according to claim 1, wherein the barrier layer has a porosity ratio in the range from about 20% to about 90%.

3. The silicon thin film transistor according to claim 2, wherein the barrier layer has a thickness in the range from 30% to 60%.

4. The silicon thin film transistor according to claim 1, wherein the barrier layer has a thickness in the range from about 150 nm to about 1000 nm.

5. The silicon thin film transistor according to claim 4, wherein the barrier layer has a thickness in the range from about 400 nm to about 600 nm.

6. The silicon thin film transistor according to claim 1, wherein the thin film has a thickness in the range from about 20 nm to about 80 nm.

7. The silicon thin film transistor according to claim 6, wherein the thin film has a thickness in the range from about 50 nm to about 80 nm.

8. The silicon thin film transistor according to claim 1, wherein the size of the grains of polycrystalline silicon in the thin film is greater than or equal to 1 μm.

9. The silicon thin film transistor according to claim 1, wherein the substrate is made of glass.

10. A method of manufacturing a silicon thin film transistor, the method comprising the following steps:
a) depositing a porous silica barrier layer directly on a substrate;
b) depositing an amorphous silicon thin film directly on the barrier layer; and
c) irradiating the amorphous silicon thin film using a laser to obtain a thin film of polycrystalline silicon.

11. The method according to claim 10, wherein said method further comprises, between step b) and step c), a step of dehydrogenating the amorphous silicon thin film.

12. The method according to claim 10, wherein in step a), the barrier layer of porous silica is deposited by a sol-gel method.

13. The method according to claim 10, wherein in step b), the amorphous silicon thin film is deposited by plasma-assisted chemical vapor deposition.

14. The method according to claim 10, wherein in step c) irradiation is performed using an excimer layer.

15. The method according to claim 14, wherein in step c) irradiation is operating at 248 nm or at 308 nm.

16. The method according to claim 15, wherein step c) is performed with an excimer laser operating at 308 nm.

17. The method according to claim 10, wherein the thickness of the barrier layer lies in the range from about 150 nm to about 1000 nm.

18. The method according to claim 17, wherein the thickness of the barrier layer is in the range from about 400 nm to about 600 nm.

19. The method according to claim 10, wherein the porosity ratio of the barrier layer lies in the range from about 20% to about 90%.

20. The method according to claim 19, wherein the porosity ratio of the barrier layer is in the range from about 30% to about 60%.

21. The method according to claims 10, wherein the thickness of both the amorphous and polycrystalline silicon thin film lies in the range from about 20 nm to about 80 nm.

22. The method according to claim 21, wherein the thickness of both the amorphous and polycrystalline silicon thin film is in the range from 50 nm to 80 nm.

23. The method according to claim 10, wherein the substrate is made of glass.

24. A display screen, characterized in that it includes at least one polycrystalline silicon thin film transistor according to either claim 1 or 10.

25. A method of manufacturing a display screen, characterized in that it includes the method of manufacturing a polycrystalline silicon thin film transistor according to claim 10.
